(19) United States
(12) Patent Application Publication
(10) Pub. No.: US 2025/0232986 A1
(43) Pub. Date: Jul. 17, 2025

(54) SUBSTRATE PROCESSING APPARATUS AND SUBSTRATE PROCESSING METHOD

(71) Applicant: SAMSUNG ELECTRONICS CO., LTD., Suwon-si (KR)

(72) Inventors: Junho Lee, Suwon-si (KR); Sungjun Noh, Suwon-si (KR); Jihoon Jeong, Suwon-si (KR); Songyun Kang, Suwon-si (KR); Taeheon Kim, Suwon-si (KR); Younghoo Kim, Suwon-si (KR); Junho Yoon, Suwon-si (KR); Jongwon Lee, Suwon-si (KR); Jiwoong Jung, Suwon-si (KR); Jeonghwa Hong, Suwon-si (KR)

(73) Assignee: SAMSUNG ELECTRONICS CO., LTD., Suwon-si (KR)

(21) Appl. No.: 18/910,754

(22) Filed: Oct. 9, 2024

(30) Foreign Application Priority Data
Jan. 17, 2024 (KR) 10-2024-0007632

(51) Int. Cl. H01L 21/67; B08B 7/00; H01L 21/02

(52) U.S. Cl. CPC H01L 21/67034; B08B 7/0021; H01L 21/02101

(57) ABSTRACT

A substrate processing apparatus includes a processing chamber including a processing space, a substrate support that receives a substrate and support the substrate in the processing chamber, a fluid supply pipe arranged at a lower portion of the processing chamber, and a fluid supply device that supplies a processing fluid to the processing space through the fluid supply pipe. The processing chamber includes a step portion and a round portion both in an upper surface that defines the processing space, and a first horizontal separation distance from a center of the processing chamber to the step portion is greater than a second horizontal separation distance from the center of the processing chamber to an edge of the substrate.

### CROSS-REFERENCE TO RELATED APPLICATION

This application is based on and claims priority under 35 U.S.C. § 119 to Korean Patent Application No. 10-2024-0007632, filed on Jan. 17, 2024 in the Korean Intellectual Property office, the disclosure of which being incorporated by reference herein in its entirety.

### BACKGROUND

Apparatuses and methods consistent with the present disclosure relate to a substrate processing apparatus and a substrate processing method and, more particularly, to a substrate processing apparatus, which uses a supercritical fluid, and a substrate processing method.

As semiconductor devices are required to be fine, an extreme ultra-violet (EUV) lithography method using a very short wavelength has been proposed. By using the EUV lithography, a photoresist pattern having a small horizontal dimension and a high aspect ratio may be formed. To reduce the fall or collapse of the photoresist pattern in the process of forming a fine photoresist pattern, a drying process using a supercritical fluid is being used, but issues to be improved still remain.

### SUMMARY

It is an aspect to provide a substrate processing apparatus capable of improving uniformity in substrate processing by preventing a leaning phenomenon of a fine pattern at a substrate edge.

According to an aspect of one or more embodiments, there is provided a substrate processing apparatus comprising a processing chamber including a processing space; a substrate support configured to receive a substrate and support the substrate in the processing chamber; a fluid supply pipe arranged at a lower portion of the processing chamber; and a fluid supply device configured to supply a processing fluid to the processing space through the fluid supply pipe. The processing chamber comprises a step portion and a round portion both in an upper surface that defines the processing space, and a first horizontal separation distance from a center of the processing chamber to the step portion is greater than a second horizontal separation distance from the center of the processing chamber to an edge of the substrate.

According to another aspect of one or more embodiments, there is provided a substrate processing apparatus comprising a processing chamber including a processing space; a substrate support configured to receive a substrate and support the substrate in the processing chamber; a fluid supply pipe arranged at a lower portion of the processing chamber; and a fluid supply device configured to supply a processing fluid to the processing space through the fluid supply pipe. The processing chamber comprises a step portion and a round portion on an upper surface that defines the processing space, and the step portion is vertically aligned with an edge of the substrate.

According to yet another aspect of one or more embodiments, there is provided a substrate processing method comprising loading a substrate into a processing space of a processing chamber; supplying a processing fluid into the processing chamber through at least one of a first supply pipe provided on a bottom wall of the processing chamber or a second supply pipe provided on an upper wall of the processing chamber; and exhausting the processing fluid in the processing chamber through an exhaust pipe provided on the bottom wall of the processing chamber. The processing chamber comprises an upper processing chamber and a lower processing chamber, and wherein the upper processing chamber comprises a step portion and a round portion.

### BRIEF DESCRIPTION OF THE DRAWINGS

Various embodiments will be more clearly understood from the following detailed description taken in conjunction with the accompanying drawings, in which:

FIG. 1 is a cross-section view of a substrate processing apparatus according to an embodiment;

FIG. 2 is an enlarged cross-sectional view of region A in FIG. 1;

FIG. 3 is a cross-section view of a substrate processing apparatus according to an embodiment;

FIG. 4 is a cross-section view of a substrate processing apparatus according to an embodiment;

FIG. 5 is a configuration diagram of a fluid supply device of a substrate processing apparatus, according to an embodiment;

FIGS. 6 and 7 are simulation diagrams illustrating a flow rate of a processing fluid according to an experimental example of a substrate processing apparatus according to an embodiment; and

FIG. 8 is a simulation diagram illustrating a flow rate of a processing fluid according to a comparison example according to the related art;

FIGS. 9 and 10 are simulation diagrams illustrating a direction of a particle blocking flow according to an experiment example of a substrate processing apparatus according to an embodiment; and

FIG. 11 is a simulation diagram of a direction of the particle blocking flow, according to a comparison example according to the related art;

FIGS. 12 through 14 are simulation diagrams of flow rates of a processing fluid, according to a comparison example according to the related art;

FIG. 15 is a flowchart of a substrate processing method according to an embodiment;

FIG. 16 is a graph of a change of pressure inside a processing chamber while a substrate processing is performed, according to an embodiment;

FIG. 17 is a plan view of an entire arrangement of a substrate processing apparatus, according to an embodiment;

FIG. 18 is a flowchart of a fine pattern forming method using a substrate processing apparatus, according to an embodiment; and

FIGS. 19 through 21 are cross-sectional views for explaining the fine pattern forming method of FIG. 18 according to a process sequence, according to an embodiment.

### DETAILED DESCRIPTION

Hereinafter, various embodiments are described in detail with reference to the accompanying drawings. Identical reference numerals are used for the same components in the drawings, and a duplicate description thereof will be omitted for conciseness. In the following drawings, a thickness or size of each layer is exaggerated for convenience and clarity of description, and thus may differ from an actual shape or ratio. As used in this specification, the phrase “at least one of A or B” includes within its scope “only A”, “only B”, and “A and B.”

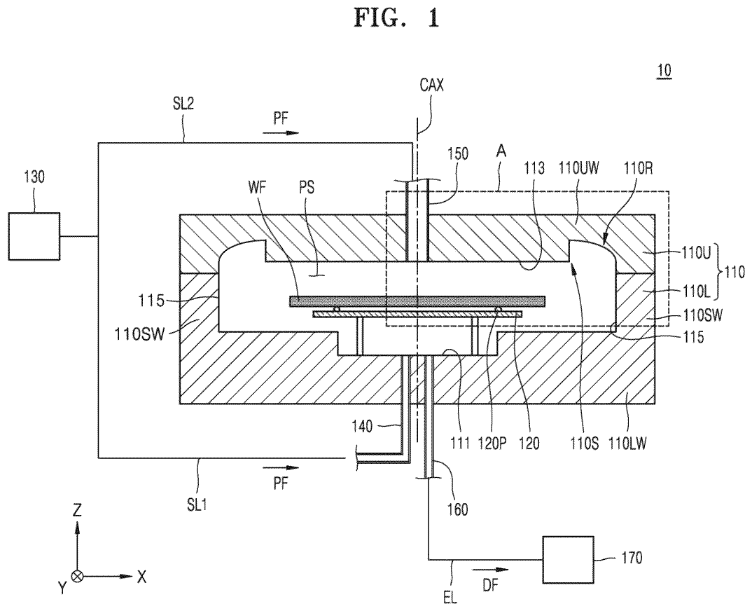

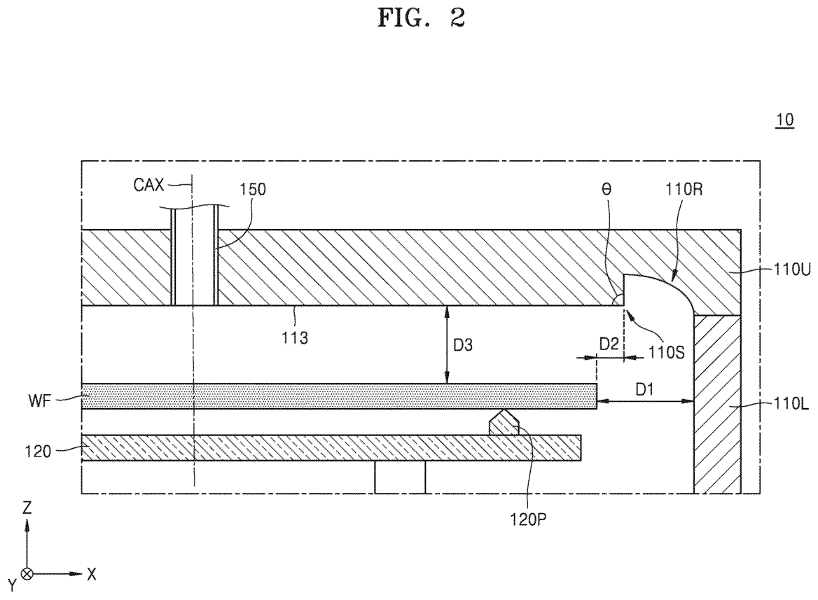

FIG. 1 is a cross-section view of a substrate processing apparatus 10 according to an embodiment, and FIG. 2 is an enlarged cross-sectional view of region A in FIG. 1.

Referring to FIGS. 1 and 2, the substrate processing apparatus 10 may include a processing chamber 110, a substrate support 120, a fluid supply device 130, a first supply pipe 140, a second supply pipe 150, an exhaust pipe 160, and an exhaust device 170.

The processing chamber 110 may provide a processing space PS for processing a substrate WF. The processing chamber 110 may seal the processing space PS from the outside, while the substrate WF is being processed. The processing space PS may be defined by a lower surface 111, an upper surface 113, and a side surface 115 of an interior of the processing chamber 110. In other words, the processing space PS may be defined by a lower wall 110LW including the lower surface 111 of the processing chamber 110, an upper wall 110UW including the upper surface 113 of the processing chamber 110, and a sidewall 110SW defining the side surface 115 of the processing chamber 110.

In some embodiments, the processing space PS may have a symmetrical shape with respect to a center axis CAX of the processing chamber 110. For example, in an embodiment, the processing space PS may have a rotational symmetrical shape with respect to the center axis CAX of the processing chamber 110. For example, the processing chamber 110 and the processing space PS may have a symmetrical shape or a mirror shape with respect to an arbitrary reference plane. In some embodiments, the processing chamber 110 and the processing space PS may not have a symmetrical shape. In some embodiments, an upper body 110U of the processing chamber 110 may have a symmetrical shape with respect to the center axis CAX of the processing chamber 110.

In some embodiments, the processing chamber 110 may include a lower body 110L and an upper body 110U. The upper body 110U may be arranged on the lower body 110L. Each of the upper body 110U and the lower body 110L may include, for example, a metal material. The upper body 110U may be coupled onto the lower body 110L to cover a space provided by the lower body 110L. The upper body 110U and the lower body 110L may be switched between a closed position for sealing the processing space PS and an open position for opening the processing space PS to the atmosphere outside the processing chamber 110.

At the closed position of the processing chamber 110, the upper body 110U may be coupled onto the lower body 110L to seal the processing space PS. At the open position of the processing chamber 110, the upper body 110U may be apart from the lower body 110L, and the processing space PS may be open to the atmosphere outside the processing chamber 110. Switching between the closed position and the open position of the processing chamber 110 may be implemented by using an elevating device (not illustrated) configured to move the upper body 110U in a vertical direction (Z direction) with respect to the lower body 110L.

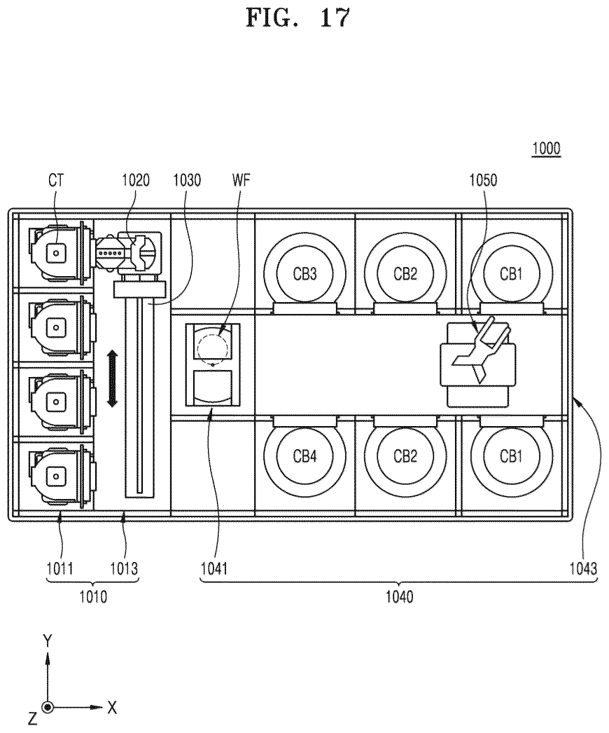

In all figures except for FIG. 17, a direction in parallel with a main surface of the substrate WF is defined as a horizontal direction (X direction and/or Y direction) and a direction perpendicular to the horizontal direction (X direction and/or Y direction) is defined as a vertical direction (Z direction).

The upper body 110U may include a step portion 110S and a round portion 110R on the lower surface of the upper body 110U. That is, the step portion 110S and the round portion 110R may be formed on the upper surface 113 of the processing chamber 110. In other words, the processing chamber 110 may include the step portion 110S and the round portion 110R on an upper surface of the processing space PS. The step portion 110S may be formed by being recessed in a vertical upward direction (+Z direction) on the upper surface 113 of the interior of the processing chamber 110. In other words, the step portion 110S may be recessed vertically into the upper body 110U. The step portion 110S and the round portion 110R may be in contact with each other. A horizontal separation distance from the center of the substrate WF to the step portion 110S may be less than a horizontal separation distance from the center of the substrate WF to the round portion 110R. Stated another way, a horizontal separation distance from a center of the processing chamber 110 to the step portion 110S may be less than the horizontal separation distance from the center of the processing chamber 110 to the round portion 110R. A vertical level of the round portion 110R may decrease away from the center of the substrate WF. Stated another way, the vertical level of the round portion 110R may decrease away from the center of the processing chamber 110.

The flow rate of the processing fluid PF and the distribution of the flow rate of the processing fluid PF on the substrate WF may be reduced by the step portion 110S of the substrate processing apparatus 10. A detailed description thereof is described below. A size of a dead zone, in which particles introduced from the outside of the processing chamber 110 maintain positions thereof, may be reduced by the round portion 110R of the substrate processing apparatus 10. A detailed description thereof is described below.

The step portion 110S may form a certain angle θ with the upper surface 113 of the interior of the processing chamber 110. For example, in an embodiment, the angle θ of the step portion 110S may be about 90°.

A horizontal separation distance from the center axis CAX to the edge of the substrate WF may be less than the horizontal separation distance from the center axis CAX to the step portion 110S. In other words, the horizontal separation distance from the edge of the substrate WF to the side surface 115 of the processing chamber 110 may be greater than the horizontal separation distance from the step portion 110S to the side surface 115 of the processing chamber 110.

A first distance D1, which is a horizontal distance from the edge of the substrate WF to the side surface 115 of the processing chamber 110, may be greater than a second distance D2, which is a horizontal distance from the edge of the substrate WF to the step portion 110S. The second distance D2 may be about ⅔ or less of the first distance D1.

An upper surface of the substrate WF and the upper surface 113 of the processing chamber 110 may be spaced apart from each other by a third distance D3 in the vertical direction (Z direction). For example, in an embodiment, the third distance D3 may be about 2 mm to about 10 mm. For example, in an embodiment, when the processing fluid PF is carbon dioxide (CO₂) and a fraction of the processing fluid PF is about 0.96, the third distance D3 may be about 4 mm or more. The third distance D3 may vary depending on the type of the processing fluid PF and the fraction of the processing fluid PF.

The substrate support 120 may be provided in the processing space PS, and may support the substrate WF. The substrate support 120 may support the substrate WF so that the upper surface of the substrate WF faces the upper surface 113 of the processing chamber 110 and a lower surface of the substrate WF faces the lower surface 111 of the processing chamber 110. The upper surface of the substrate WF may include a surface to be processed by using the substrate processing apparatus 10. The substrate support 120 may be coupled to the lower wall 110LW of the processing chamber 110.

The substrate support 120 may have a shape corresponding to the substrate WF. For example, in some embodiments, the shape may be a disk shape. The substrate support 120 may include, for example, a metal material or a ceramic material. For example, the substrate support 120 may include a block plate. The substrate support 120 may be supported by a support pillar on the lower surface 111 of the processing chamber 110 and may be apart from the lower surface 111 of the processing chamber 110 by a preset distance. The substrate support 120 may be arranged on the lower surface 111 of the processing chamber 110 to cover the first supply pipe 140 and the exhaust pipe 160.

The substrate support 120 may be arranged between the first supply pipe 140 and the substrate WF and adjust the flow direction of the processing fluid PF injected through the first supply pipe 140. The substrate support 120 may block the processing fluid PF, injected through the first supply pipe 140, from being directly sprayed onto the lower surface of the substrate WF. The substrate support 120 may guide the processing fluid PF so that the processing fluid PF injected through the first supply pipe 140 flows in the horizontal direction (X direction and/or Y direction) or in the lateral direction.

A support pin 120P may be arranged on the substrate support 120, and the substrate WF may be supported by the support pin 120P in contact with the lower surface of the substrate WF. In this case, the diameter of the substrate support 120 may be less than the diameter of the substrate WF.

The fluid supply device 130 may generate the processing fluid PF for treating the substrate WF and supply the generated processing fluid PF to the processing space PS of the processing chamber 110. In some embodiments, the fluid supply device 130 may be configured to generate and supply a supercritical fluid, and the substrate processing apparatus 10 may be configured to use the supercritical fluid to process the substrate WF. For example, the substrate processing apparatus 10 may be configured to perform a drying process on the substrate WF by using a supercritical fluid.

Physical properties, such as density, viscosity, a diffusion coefficient, polarity, or the like, of the supercritical fluid may continuously change from a gas-like state to a liquid-like state according to a change in pressure. The supercritical fluid may include a material having a temperature equal to or greater than a critical temperature and a pressure equal to or greater than critical pressure, may have diffusivity, viscosity, and surface tension in a gas-like state, and may also have solubility in a liquid-like state. When a drying process is performed on the substrate WF by using a supercritical fluid, the supercritical fluid having little surface tension may penetrate into a fine groove provided in the substrate WF and may dry a cleaning solution or a rinse solution on the substrate WF, while suppressing a significant portion of falling, collapse, or a leaning phenomenon (hereinafter, the leaning phenomenon) occurring in the fine pattern on the substrate WF.

For example, the supercritical fluid may include CO₂, water (H₂O), methane (CH₄), ethane (C₂H₆), propane (C₃H₈), ethylene (C₂H₄), propylene (C₂H₂), methanol (C₂H₃OH), ethanol (C₂H₅OH), sulfur hexafluoride (SF₆), acetone (C₃H₈O), or a combination thereof. In some embodiments, the fluid supply device 130 may be configured to generate and supply a supercritical fluid containing CO₂. Because CO₂ has a low critical temperature and critical pressure of about 31° C. and about 73 bar, respectively, and is non-toxic, non-flammable, and relatively inexpensive, CO₂ may be easily used for drying the substrate WF.

The fluid supply device 130 may be configured to supply the processing fluid PF to the processing space PS of the processing chamber 110 via at least one of the first supply pipe 140 arranged on the lower wall 110LW of the processing chamber 110 or the second supply pipe 150 arranged on the upper wall 110UW of the processing chamber 110.

The first supply pipe 140 may extend from the lower wall 110LW of the processing chamber 110. The first supply pipe 140 may extend downward from the lower surface 111 of the processing chamber 110. For example, the first supply pipe 140 may be inserted into the lower wall 110LW of the processing chamber 110.

The processing fluid PF provided by the fluid supply device 130 may be provided to the first supply pipe 140 via a first supply line SL1, and an on/off valve for controlling the supply of the processing fluid PF to the first supply pipe 140 may be installed on the first supply line SL1. The processing fluid PF may be injected into the processing space PS through the first supply pipe 140. In some embodiments, the first supply pipe 140 may have a circular or elliptical shape in a plan view. In some embodiments, the first supply pipe 140 may have a polygonal shape such as a square in a plan view.

The second supply pipe 150 may extend from the upper wall 110UW of the processing chamber 110. The second supply pipe 150 may extend from the upper surface 113 of the processing chamber 110 in the vertical upward direction (+Z direction). For example, the second supply pipe 150 may be inserted into the upper wall 110UW of the processing chamber 110.

The processing fluid PF provided by the fluid supply device 130 may be provided to the second supply pipe 150 through a second supply line SL2, and an on/off valve for controlling the supply of the processing fluid PF to the second supply pipe 150 may be installed in the second supply line SL2. The processing fluid PF may be injected into the processing space PS through the second supply pipe 150. In some embodiments, the second supply pipe 150 may have a circular or elliptical shape in a plan view. In some embodiments, the second supply pipe 150 may have a polygonal shape such as a square in a plan view.

The exhaust pipe 160 may extend from the lower wall 110LW of the processing chamber 110. The exhaust pipe 160 may extend downward from the lower surface 111 of the processing chamber 110. For example, the exhaust pipe 160 may be inserted into the lower wall 110LW of the processing chamber 110.

The exhaust pipe 160 may be connected to the exhaust device 170 via an exhaust line EL. By performing the exhaust operation of the exhaust device 170, a discharge fluid DF of the processing space PS may be sucked into the exhaust pipe 160. In some embodiments, the exhaust pipe 160 may have a circular or elliptical shape in a plan view. In some embodiments, the exhaust pipe 160 may have a polygonal shape such as a square in a plan view.

The exhaust device 170 may be configured to discharge the discharge fluid DF of the processing space PS to the outside of the processing chamber 110. The exhaust device 170 may be connected to the exhaust pipe 160 on the lower wall 110LW of the processing chamber 110 via the exhaust line EL.

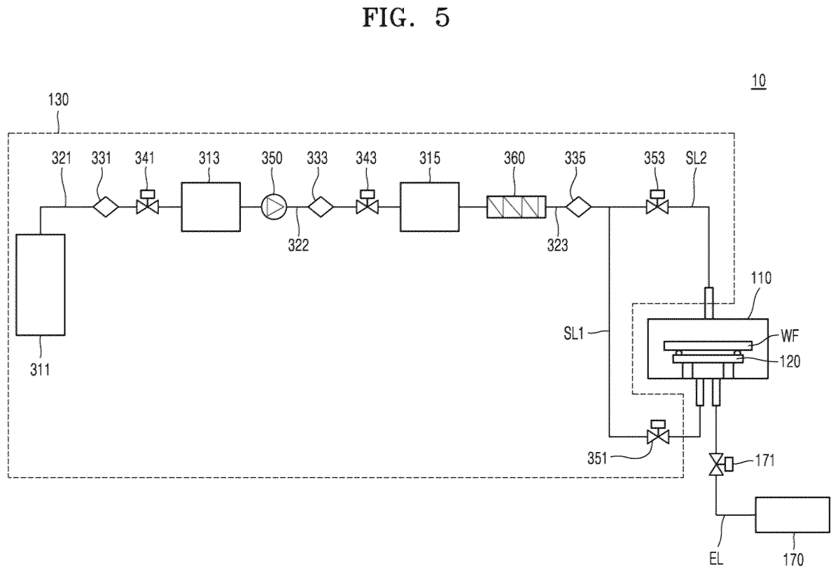

In this case, the discharge fluid DF may be defined as a fluid including various gases, chemicals, by-products, particles, the processing fluid PF, or the like in the processing space PS. The discharge fluid DF may be discharged from the processing space PS via the exhaust pipe 160. The exhaust device 170 may include a vacuum pump, a recovery unit for recovering the discharge fluid DF, an on/off valve (refer to 171 in FIG. 5) installed on the exhaust line EL, a flowmeter installed on the exhaust line EL, etc. For example, to perform an exhaust operation by using the exhaust device 170, the vacuum pump may reduce the pressure in the exhaust pipe 160, and suck the discharge fluid DF in the processing space PS into the exhaust pipe 160. In some embodiments, the exhaust device 170 may be configured to control the pressure in the processing space PS by sucking and removing the discharge fluid DF in the processing space PS.

As semiconductor devices are required to be fine, an extreme ultra-violet (EUV) lithography method using a short wavelength has been proposed. By using the EUV lithography, a photoresist pattern having a small horizontal dimension and a high aspect ratio may be formed. To reduce the fall or collapse of the photoresist pattern in the process of forming a fine photoresist pattern, a drying process using a supercritical fluid is being used.

A supercritical fluid with almost no surface tension is widely used because the supercritical fluid penetrates into fine grooves provided in the substrate WF, significantly suppresses the lean phenomenon of a pattern that may occur in the fine patterns on the substrate WF, and dries the cleaning liquid or rinse liquid.

However, in the related art, due to the processing fluid PF supplied at high pressure through the first supply pipe 140 in the early stage of a dry process, turbulence having a high flow rate may occur on the substrate WF. The turbulence generated in this manner may be formed very close to or overlap the substrate WF and affect the fine pattern formed at the edge of the substrate WF, and thus, a leaning phenomenon issue of the fine pattern may occur.

To address this disadvantage with the related art, the substrate processing apparatus 10 according to one or more embodiments may include the step portion 110S and the round portion 110R on the lower surface of the upper body 110U of the processing chamber 110. Because the substrate processing apparatus 10 includes the step portion 110S, the flow rate of the processing fluid PF and/or the distribution of the flow rate of the processing fluid PF on the substrate WF may be reduced. Because the substrate processing apparatus 10 includes the round portion 110R, the size of the dead zone inside the processing chamber 110 may be reduced. Thus, the substrate processing apparatus 10 according to one or more embodiments may effectively prevent the leaning phenomenon of fine patterns at the edge of the substrate WF and improve the uniformity of the substrate WF drying process.

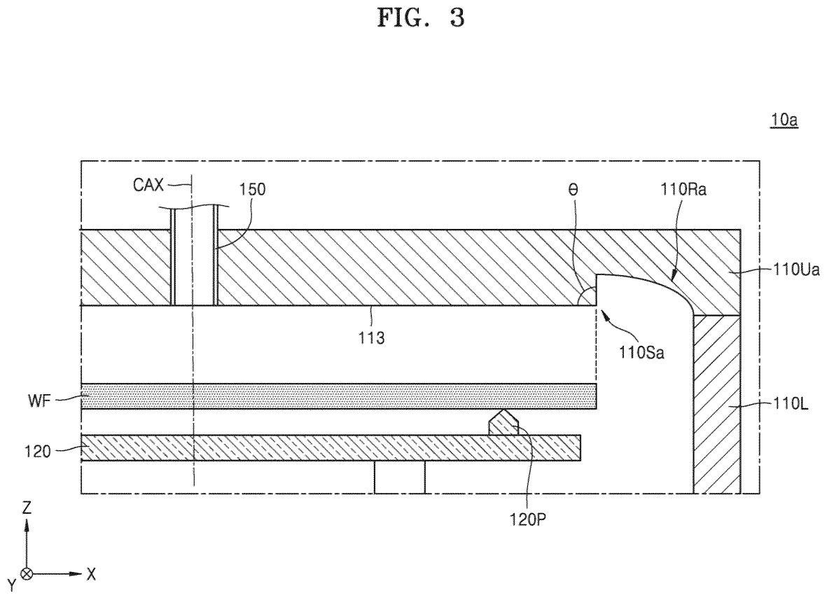

FIG. 3 is a cross-sectional view of a substrate processing apparatus 10a according to an embodiment. FIG. 3 is an enlarged cross-sectional view illustrating a region corresponding to the region A in FIG. 1. FIG. 3 is described with reference to FIGS. 1 and 2.

Referring to FIG. 3, an upper chamber 110Ua of the substrate processing apparatus 10a may include a step portion 110Sa and a round portion 110Ra. The edge of the substrate WF may be vertically aligned with the step portion 110Sa in the vertical direction (Z direction). In this case, an angle θ of the step portion 110Sa may be about 90°.

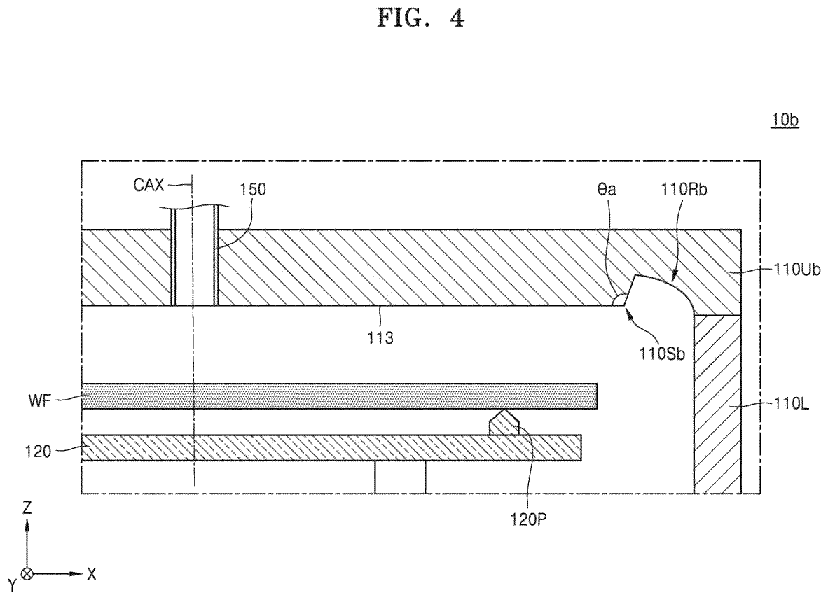

FIG. 4 is a cross-sectional view of a substrate processing apparatus 10b according to an embodiment. FIG. 4 is an enlarged cross-sectional view of a region corresponding to region A in FIG. 1. FIG. 4 is described with reference to FIGS. 1 through 3.

Referring to FIG. 4, an upper chamber 110Ub of the substrate processing apparatus 10b may include a step portion 110Sb and a round portion 110Rb. The edge of the substrate WF may not be vertically aligned with the step portion 110Sb in the vertical direction (Z direction). The distance from the center axis CAX to the edge of the substrate WF may be less than the distance from the center axis CAX to the step portion 110Sb.

In an embodiment, an angle θₐ of the step portion 110Sb with respect to the upper surface 113 of the processing chamber 110 may be about 90° to about 180°. When the distance from the center axis CAX to the edge of the substrate WF is less than the distance from the center axis CAX to the step portion 110Sb, the angle θₐ of the step portion 110Sb may be about 90° to about 180°.

As illustrated in FIG. 3, when the step portion 110Sa is aligned with the edge of the substrate WF in the vertical direction (Z direction), the angle θ of the step portion 110Sa may be about 90°.

FIG. 5 is a configuration diagram of a fluid supply device 130 of the substrate processing apparatus 10, according to an embodiment. FIG. 5 is described with reference to FIGS. 1 and 2.

Referring to FIG. 5, the fluid supply device 130 may include a fluid supply tank 311, a condenser 313, a pump 350, a storage tank 315, and a heating device 360.

The fluid supply tank 311 may contain a raw material. For example, the fluid supply tank 311 may store the processing fluid PF in a gas-like state. The condenser 313 may change the phase of the processing fluid PF. The condenser 313 may cool the processing fluid PF so that the processing fluid PF changes from the gas-like state to a liquid-like state. On a first fluid line 321 connecting the fluid supply tank 311 to the condenser 313, a filter 331 for filtering impurities in the processing fluid PF and a valve 341 for controlling the flow of the processing fluid PF may be installed.

The pump 350 may be installed on a second fluid line 322 extending between the condenser 313 and the storage tank 315. The pump 350 may drive the processing fluid PF so that the processing fluid PF liquefied by the condenser 313 is supplied to the storage tank 315 through the second fluid line 322. On the second fluid line 322 connecting the condenser 313 to the storage tank 315, a filter 333 for filtering impurities in the processing fluid PF and a valve 343 for controlling the flow of the processing fluid PF may be installed.

The storage tank 315 may store the processing fluid PF and change the phase of the processing fluid PF to a supercritical state. The storage tank 315 may heat the processing fluid PF by using an embedded heater. The embedded heater of the storage tank 315 may heat the processing fluid PF above a critical temperature of the processing fluid PF. Accordingly, the processing fluid PF discharged from the storage tank 315 may be in the supercritical state. The processing fluid PF discharged from the storage tank 315 may flow along a third fluid line 323 and then may flow through the first supply line SL1 extending from one end of the third fluid line 323 toward the first supply pipe 140 of the processing chamber 110 and/or flow through the second supply line SL2 extending from one end of the third fluid line 323 toward the second supply pipe 150 of the processing chamber 110.

On the third fluid line 323, the heating device 360 configured to heat the processing fluid PF discharged from the storage tank 315 and a filter 335 for filtering impurities in the processing fluid PF may be installed. The heating device 360 may control the temperature of the processing fluid PF provided to the processing chamber 110, by heating the processing fluid PF, which moves through the third fluid line 323. The heating device 360 may include an electric resistance-type heater. The heating device 360 may include an inline heater and/or a jacket heater installed on the third fluid line 323. A valve 351 for controlling the flow of the processing fluid PF may be installed on the first supply line SL1, and a valve 353 for controlling the flow of the processing fluid PF may be installed on the second supply line SL2.

Each of the first through third fluid lines 321 through 323 may include, for example, a pipe.

The fluid supply device 130 may differently control a first temperature of the processing fluid PF provided to a lower portion of the processing chamber 110 via the first supply pipe 140 and a second temperature of the processing fluid PF provided to the upper portion of the processing chamber 110 via the second supply pipe 150. For example, the first temperature and the second temperature of the processing fluid PF may be controlled by the heating device 360 and/or the heater of the storage tank 315. In some embodiments, the first temperature of the processing fluid PF provided to the lower portion of the processing chamber 110 through the first supply pipe 140 may be lower than the second temperature of the processing fluid PF provided to the upper portion of the processing chamber 110 through the second supply pipe 150.

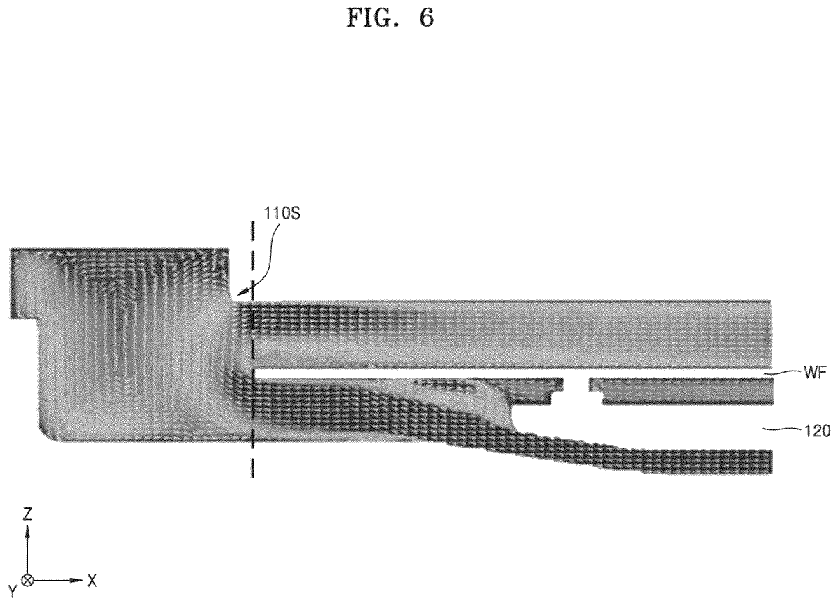

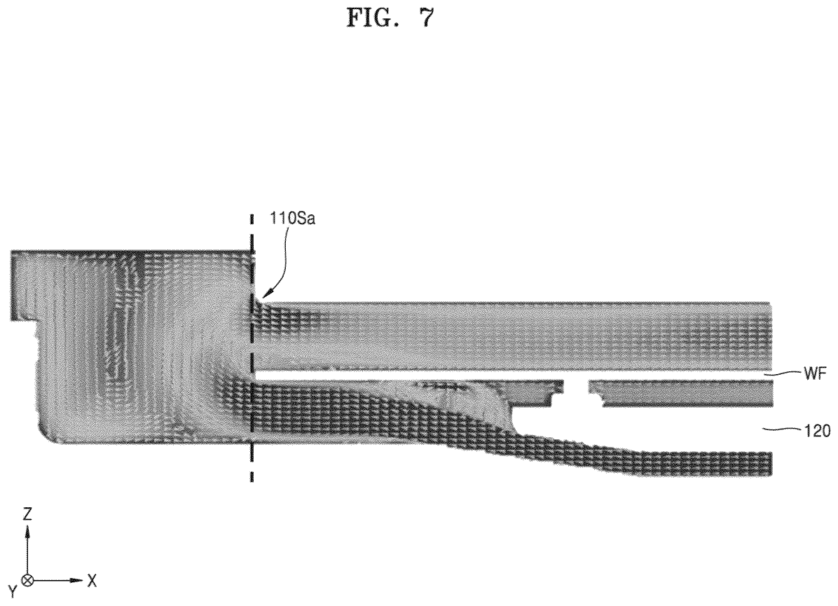

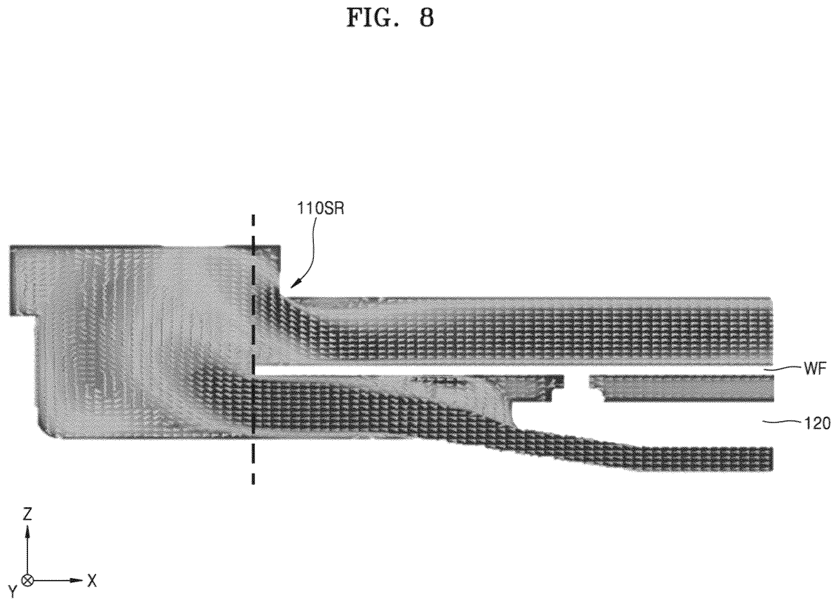

FIGS. 6 and 7 are simulation diagrams illustrating a flow rate of the processing fluid PF according to an experiment example of an embodiment, and FIG. 8 is a simulation diagram illustrating a flow rate of the processing fluid PF according to a comparison example according to the related art. In FIGS. 6 to 8, the dashed line indicates a line extending from the edge of the substrate WF in the vertical direction (Z direction). In FIG. 6, a distance from the center of the substrate WF to a step portion 110S may be greater than a distance from the center of the substrate WF to the edge of the substrate WF in the horizontal direction (X direction and/or Y direction), and in FIG. 7, the step portion 110Sa is vertically aligned with the edge of the substrate WF in the vertical direction (Z direction). In FIG. 8, a distance from the center of the substrate WF to a step portion 110SR may be less than a distance from the center of the substrate WF to the edge of the substrate WF in the horizontal direction (X direction and/or Y direction). For example, FIG. 6 may illustrate a portion of the substrate processing apparatus 10 of FIG. 2, and FIG. 7 may illustrate a portion of the substrate processing apparatus 10a of FIG. 3. FIGS. 6 and 7 are described with reference to FIGS. 1 through 5.

Referring to FIGS. 6 through 8, when the step portion 110S is arranged to be more spaced apart in the horizontal direction (X direction and/or Y direction) from the center of the substrate WF than the edge of the substrate WF, and/or when the step portion 110Sa is arranged to be vertically aligned with the edge of the substrate WF in the vertical direction (Z direction), the flow rate of the processing fluid PF and/or the distribution of the flow rate of the processing fluid PF on the substrate WF may decrease. Accordingly, the leaning phenomenon of the fine pattern on the substrate WF may be efficiently prevented.

As a result, relatively fewer bad dies, which are defective products due to the leaning phenomenon of the pattern, are manufactured at the edge of the substrate WF, and thus, the number of good dies, which are good products without the leaning phenomenon of the pattern, may increase.

In other words, those of skill in the art will understand from the simulation result that in the substrate processing apparatus 10 according to one or more embodiments, the distribution of the flow rate of the processing fluid PF and/or the distribution of the flow rate of the processing fluid PF on the substrate WF decreases, and thus, the uniformity of the substrate WF processing increases and the production yield increases.

Those of skill in the art will understand from the simulation result that in the substrate processing apparatus according to the comparison example according to the related art, the flow rate of the processing fluid PF and/or the distribution of the flow rate of the processing fluid PF on the substrate WF is relatively high, and thus, the uniformity of the substrate WF processing decreases and the production yield decreases.

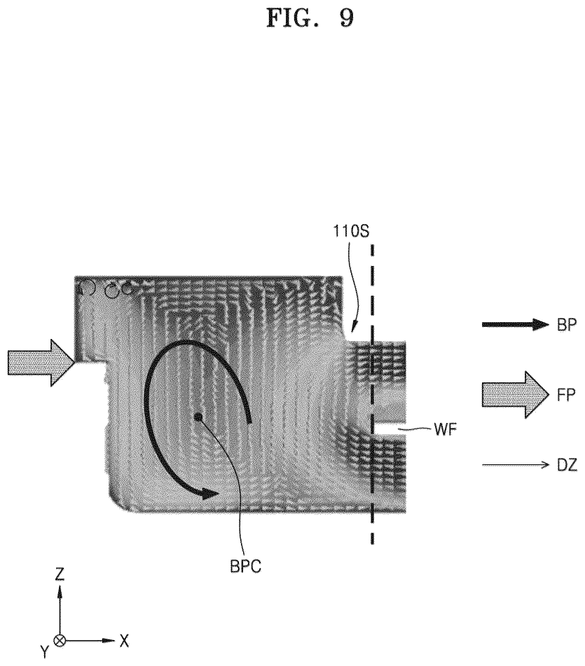

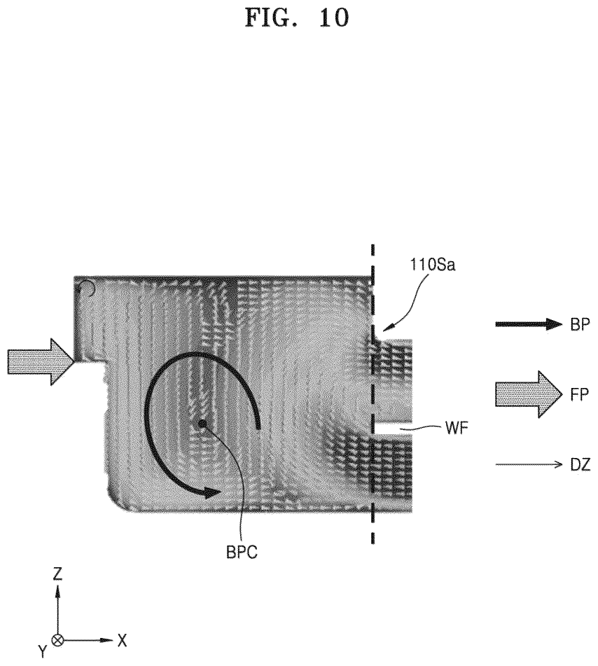

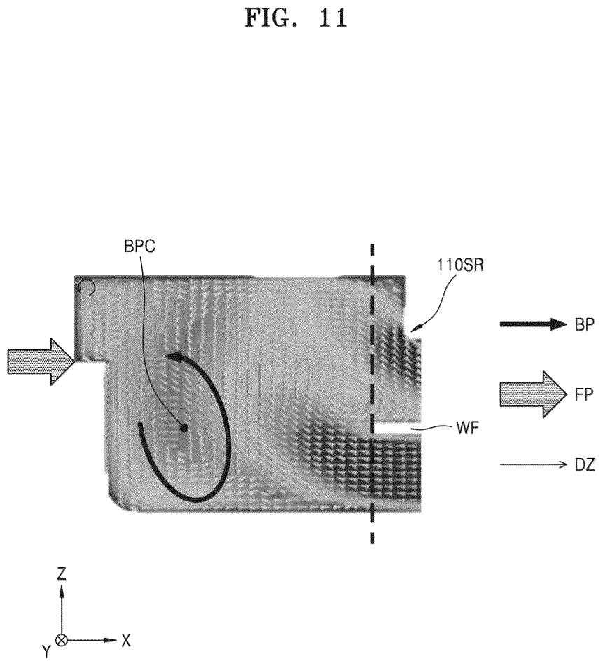

FIGS. 9 and 10 are simulation diagrams illustrating a direction of particle-blocking flow according to an experiment example of an embodiment; and FIG. 11 is a simulation diagram of a direction of particle-blocking flow, according to a comparison example according to the related art. In FIGS. 9 through 11, the dashed line may indicate a line extending from the edge of the substrate WF in the vertical direction (Z direction). In FIG. 9, a distance from the center of the substrate WF to the step portion 110S may be greater than a distance from the center of the substrate WF to the edge of the substrate WF in the horizontal direction (X direction and/or Y direction). In FIG. 10, the step portion 110Sa is vertically aligned with the edge of the substrate WF in the vertical direction (Z direction). In FIG. 11, a distance from the center of the substrate WF to the step portion 110SR may be less than a distance from the center of the substrate WF to the edge of the substrate WF in the horizontal direction (X direction and/or Y direction). For example, FIG. 9 may illustrate a portion of the substrate processing apparatus 10 of FIG. 2 and FIG. 10 may illustrate a portion of the substrate processing apparatus 10a of FIG. 3. In FIGS. 9 through 11, FP may represent a flow of a particle, BP may represent a flow of blocking the particle (that is, particle-blocking flow), and DZ may represent a dead zone. FIGS. 9 through 11 are described with reference to FIGS. 1 through 8.

Referring to FIGS. 9 through 11, at a connection portion between the upper body 110U and the lower body 110L, external particles may flow into the processing space PS of the processing chamber 110. A particle-blocking flow BP may be formed by the processing fluid PF provided to a lower portion of the processing chamber 110. The particle-blocking flow BP may be turbulence generated by the processing fluid PF. In a plan view, with respect to the center of the substrate WF, a center BPC of the particle-blocking flow BP may be positioned outside the edge of the substrate WF. Regardless of the positions of the step portions 110S, 110Sa, and 110SR, the particle-blocking flow BP may be outside the edge of the substrate WF with respect to the center of the substrate WF in a plan view.

A dead zone DZ may be formed on a left side of the upper portion of the processing space PS. The dead zone DZ may denote area in which particles introduced from the outside of the processing chamber 110 maintain their positions. To prevent the formation of the dead zone DZ, the round portion 110R may be used. When the processing chamber 110 includes the round portion 110R, the size of the dead zone DZ may be reduced compared to the case where the processing chamber 110 does not include the round portion 110R.

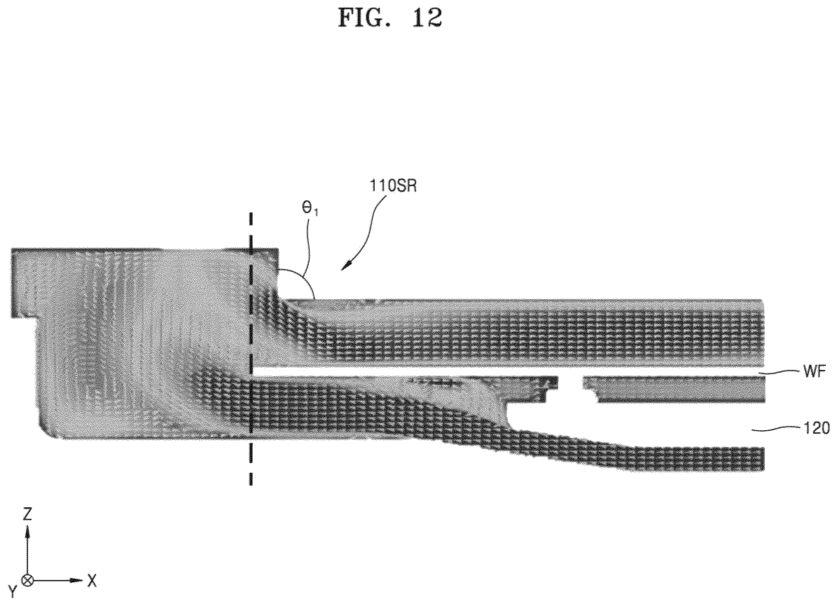

FIGS. 12 through 14 are simulation diagrams of flow rates of the processing fluid PF, according to a comparison example according to the related art. In FIGS. 12 through 14, the dashed line may indicate a line extending from the edge of the substrate WF in the vertical direction (Z direction). FIGS. 12 through 14 are described with reference to FIGS. 1 through 11.

Referring to FIGS. 12 through 14, a distance from the center of the substrate WF to each of the step portions 110SR, 110SRa, and 110SRb may be less than a distance from the center of the substrate WF to the edge of the substrate WF in the horizontal direction (X direction and/or Y direction).

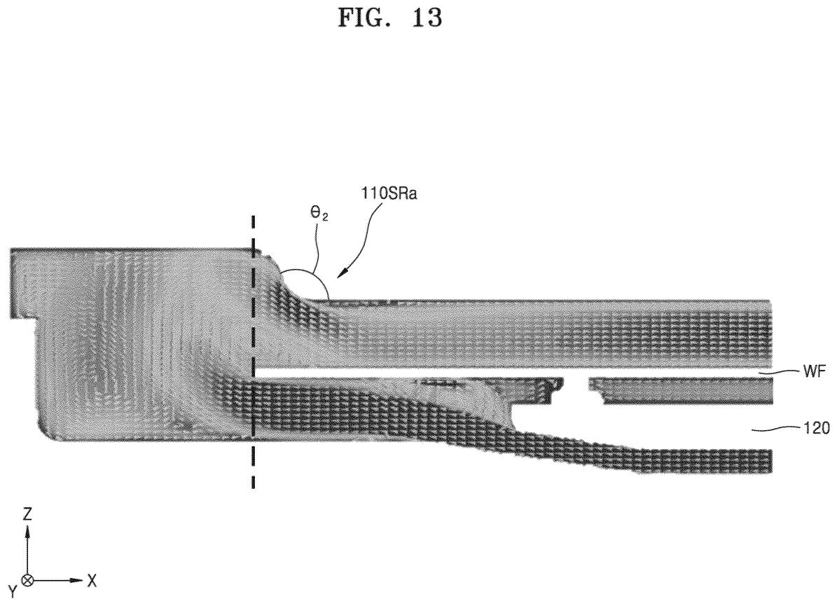

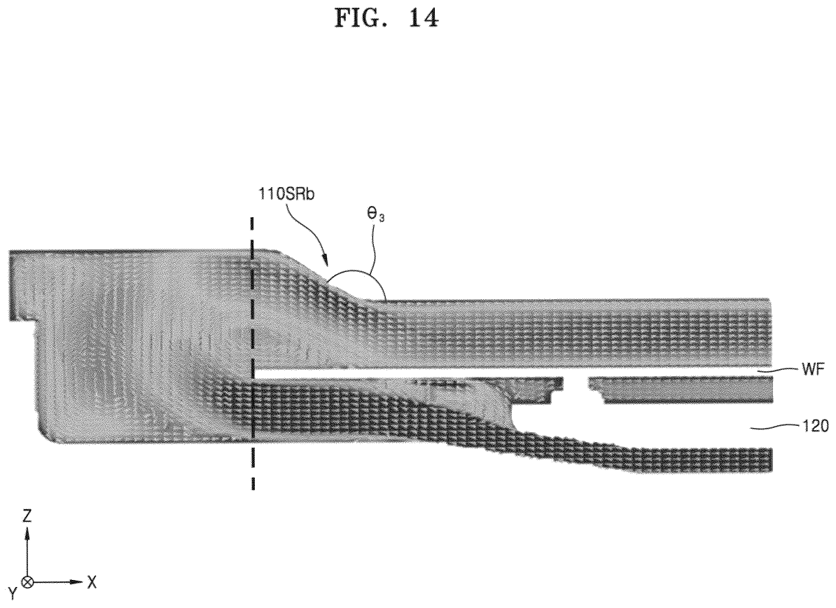

The step portion 110SR in FIG. 12 may have a first angle θ₁, the step portion 110SRa in FIG. 13 may have a second angle θ₂, and a step portion 110SRb in FIG. 14 may have a third angle θ₃. The first angle θ₁ may be about 90°, and the second and third angles θ₂ and θ₃ may be about 90° or more. The third angle θ₃ may be greater than the second angle θ₂.

As the angles of the step portions 110SR, 110SRa, and 110SRb increase, the flow rate of the processing fluid PF toward the substrate WF and the incident angle of the processing fluid PF with respect to the substrate WF may increase. In particular, when the step portions 110SR, 110SRa, and 110SRb are arranged closer to the center of the substrate WF than the edge of the substrate WF, and the angles of the step portions 110SR, 110SRa, and 110SRb exceed about 90°, the flow rate of the processing fluid PF toward the substrate WF and the incident angle of the processing fluid PF with respect to the substrate WF may increase.

Accordingly, when the angle of the step portion 110S is about 90° or more, the step portion 110S should be more apart from the center of the substrate WF in the horizontal direction (X direction and/or Y direction) than from the edge of the substrate WF. When the step portion 110Sa is aligned with the edge of the substrate WF in the vertical direction (Z direction), the angle of the step portion 110Sa may be about 90°.

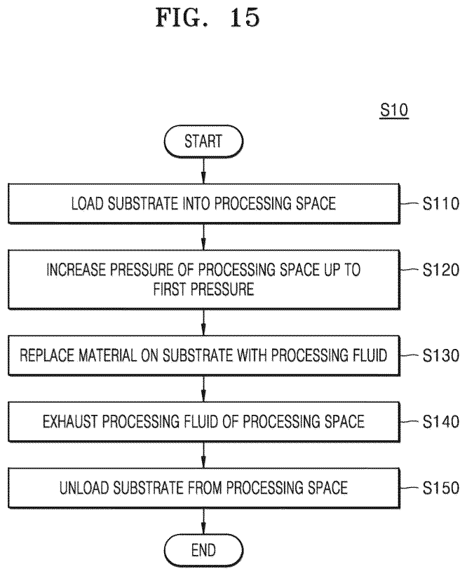

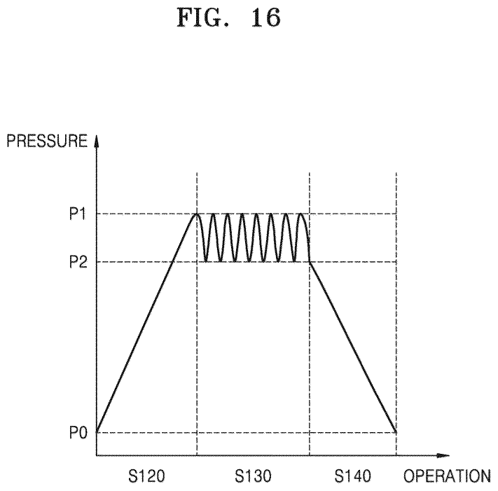

FIG. 15 is a flowchart of a substrate processing method according to an embodiment, and FIG. 16 is a graph of a change of pressure inside the processing chamber 110 while a substrate processing is performed. FIGS. 15 and 16 are described with reference to FIGS. 1 through 5.

Referring to FIGS. 15 and 16, a substrate processing method S10 using any one of the substrate processing apparatuses 10, 10a, and 10b described above is described.

In a first operation S110, the substrate WF may be loaded into the processing space PS of the processing chamber 110. While the substrate WF is loaded into the processing space PS, the processing chamber 110 may be positioned at an open position. The substrate WF may be seated on the substrate support 120. When the substrate WF is seated on the substrate support 120, the processing chamber 110 may switch from an open position to a closed position so that the processing space PS is sealed from the outside of the processing chamber 110.

When the loading operation of the substrate WF is completed, a drying process may be performed on the substrate WF. The drying process of the substrate WF may include a second operation S120 of increasing the pressure of the processing space PS to a first pressure, a third operation S130 of replacing the material on the substrate WF with the processing fluid PF, and a fourth operation S140 of exhausting the discharge fluid DF of the processing space PS.

The second operation S120 may include supplying the processing fluid PF at a supercritical state to the processing space PS so that the processing space PS is charged with the supercritical fluid. In some embodiments, by supplying the processing fluid PF at the supercritical state to the processing space PS, the fluid supply device 130 may increase the pressure in the processing space PS from an initial pressure P0 similar to the atmospheric pressure to a first pressure P1. In some embodiments, the first pressure P1 may be higher than a critical pressure of the processing fluid PF. In an embodiment, the first pressure P1 may be, for example, about 150 bar.

In some embodiments, the second operation S120 may include a first supply operation of supplying the processing fluid PF at the first temperature to the lower portion of the processing space PS via the first supply pipe 140 and a second supply operation of supplying the processing fluid PF at the second temperature to the upper portion of the processing space PS via the second supply pipe 150. In the first supply operation, the first temperature of the processing fluid PF may be about 35° C. to about 70° C. In the second supply operation, the second temperature of the processing fluid PF may be higher than the first temperature thereof. In some embodiments, in the second supply operation, the second temperature of the processing fluid PF may be about 70° C. to about 120° C.

In some embodiments, the first supply operation may be performed until the pressure of the processing space PS reaches a target intermediate pressure between the initial pressure P0 and the first pressure P1. For example, in some embodiments, the target intermediate pressure may be about 75 bar to about 90 bar. Due to such a rapid change in pressure, turbulence may occur in the processing space PS. When the pressure of the processing space PS reaches the target intermediate pressure by performing the first supply operation, the second supply operation may be performed. The second supply operation may be performed until the pressure of the processing space PS reaches the first pressure P1.

In the third operation S130, substances (for example, cleaning liquid and/or rinse liquid) on the substrate WF may be mixed (or replaced) with the processing fluid PF, and the mixed fluid may be exhausted via the exhaust pipe 160. The third operation S130 may include a decompression process of reducing the pressure of the processing space PS from the first pressure P1 to a second pressure P2 that is lower than the first pressure P1 and a boosting process of increasing the pressure of the processing space PS from the second pressure P2 to the first pressure P1. The second pressure P2 may be about 75 bars to about 90 bars.

In some embodiments, the third operation S130 may include alternately repeating the decompression process and the boosting process twice or more. The decompression process may include a discharging process of the discharge fluid DF in the processing space PS via the exhaust device 170. The boosting process may include supplying the processing fluid PF at the second temperature to the upper portion of the processing space PS via the second supply pipe 150.

In the fourth operation S140, the exhaust device 170 may exhaust the processing fluid PF in the processing space PS as discharge fluid DF and reduce the pressure of the processing space PS to the initial pressure P0.

When the drying process on the substrate WF is completed in this manner, the processing chamber 110 may be switched from the closed position to the open position, and the substrate processing method S10 may further include a fifth operation S150 of unloading the substrate WF from the processing space PS.

FIG. 17 is a plan view of an entire arrangement of a substrate processing apparatus 1000, according to an embodiment.

Referring to FIG. 17, the substrate processing apparatus 1000 may include an index module 1010, a processing module 1040, and a substrate transfer unit 1050.

The index module 1010 may include a load port 1011 and a transfer frame 1013. The load port 1011, the transfer frame 1013, and the processing module 1040 may be arranged in a row. Hereinafter, the direction in which the load port 1011, the transfer frame 1013, and the processing module 1040 are arranged in a row may be defined as the first horizontal direction (X direction), a horizontal direction perpendicular to the first horizontal direction (X direction) may be defined as the second horizontal direction (Y direction), and a direction perpendicular to each of the first horizontal direction (X direction) and the second horizontal direction (Y direction) may be defined as the vertical direction (Z direction).

A container CT, in which the substrate WF is accommodated, may be seated on the load port 1011. The load port 1011 may be provided in plurality and may be arranged in a row in the second horizontal direction (Y direction). Even though four load ports 1011 are illustrated in FIG. 17, the number of load ports 1011 may be increased or decreased according to conditions, such as process efficiency and/or installation area. The container CT may include a plurality of slots configured to support the edges of the substrate WF. The plurality of slots may be apart from each other in the vertical direction (Z direction), and accordingly, a plurality of substrates WF may be mounted on the container CT in the vertical direction (Z direction). The container CT may include, for example, a front opening unified pod (FOUP).

The transfer frame 1013 may transfer the substrate WF between the container CT on the load port 1011 and a buffer chamber 1041 of the processing module 1040. The transfer frame 1013 may include an index robot 1020 and an index rail 1030. The index rail 1030 may extend in the second horizontal direction (Y direction). The index robot 1020 may be installed on the index rail 1030 and may move linearly along the index rail 1030 in the second horizontal direction (Y direction).

The processing module 1040 may include the buffer chamber 1041, a transfer chamber 1043, and first through fourth processing chambers CB1 through CB4. The transfer chamber 1043 may extend in the first horizontal direction (X direction). In some embodiments, the first through fourth processing chambers CB1 through CB4 may be apart from each other with the transfer chamber 1043 therebetween in the second horizontal direction (Y direction). In addition, the first through fourth processing chambers CB1 through CB4 may be arranged in the first horizontal direction (X direction). In other embodiments, some of the first through fourth processing chambers CB1 through CB4 may be stacked in the vertical direction (Z direction).

In FIG. 17, the arrangement of the first through fourth processing chambers CB1 through CB4 may be an example, and in some embodiments, the first through fourth processing chambers CB1 through CB4 may be variously arranged. For example, all of the first through fourth processing chambers CB1 through CB4 may also be arranged only on one side of the transfer chamber 1043.

The buffer chamber 1041 may be arranged between the transfer frame 1013 and the transfer chamber 1043. The buffer chamber 1041 may provide a space, in which the substrate WF is stored, between the transfer chamber 1043 and the transfer frame 1013. The buffer chamber 1041 may include the plurality of slots, or the internal space, in which the substrate WF is stored. The plurality of slots may overlap each other and be apart from each other in the vertical direction (Z direction). The buffer chamber 1041 may include an opening, through which the substrate WF enter and exit, in each of a surface facing the transfer frame 1013 and a surface facing the transfer chamber 1043.

The transfer chamber 1043 may transfer the substrate WF between the buffer chamber 1041 and the first through fourth processing chambers CB1 through CB4. The substrate transfer unit 1050 may be arranged in the transfer chamber 1043. The substrate transfer unit 1050 may be installed on a rail extending in the first horizontal direction (X direction) and may move linearly along the rail in the first horizontal direction (X direction). Between the first through fourth processing chambers CB1 through CB4, the substrate WF may be transferred by the substrate transfer unit 1050.

The first through fourth processing chambers CB1 through CB4 may sequentially perform processes on one substrate WF. For example, after a developing process is performed on the substrate WF in the first processing chamber CB1, a drying process may be performed on the substrate WF in the second processing chamber CB2. A developing process may include a process of removing photoresist of a portion exposed (or not exposed) by EUV light during the exposure process. The drying process may be performed by a processing fluid PF at the supercritical state. In some embodiments, the processing fluid PF at the supercritical state may include carbon dioxide (CO₂).

The first processing chamber CB1 may supply a developer to the substrate WF in a dry state by using a spray device. The developer may include, for example, a non-polar organic solvent. The developer may include a liquid capable of selectively removing a soluble region of the photoresist by using the EUV light. In other words, due to the developer in the first processing chamber CB1, the substrate WF in a dry state may become a substrate WF in a wet state. The first processing chamber CB1 may be arranged in plurality in the processing module 1040, and the number of first processing chambers CB1 may be increased or decreased according to process efficiency and/or an installation area of the processing module 1040.

The second processing chamber CB2 may receive the substrate WF in the wet state from the first processing chamber CB1 and may remove a developer from the transferred substrate WF by using the supercritical fluid. In general, a method of rotating the substrate WF at a high speed has been used, but a photoresist pattern for the EUV light may collapse due to surface tension during a high speed rotation. To address this issue, the developer may be removed by dissolving the developer in the supercritical fluid and discharging the supercritical fluid. In this manner, by removing the developer and the supercritical fluid together from the substrate WF, the substrate WF in the wet state may be dried. In other words, due to the drying process in the second processing chamber CB2, the substrate WF in the wet state may become the substrate WF in the dry state. The second processing chamber CB2 may be arranged in plurality in the processing module 1040, and the number of second processing chambers CB2 may be increased or decreased according to process efficiency and/or an installation area of the processing module 1040. In some embodiments, the second processing chamber CB2 may include any one of the substrate processing apparatuses 10, 10a, and 10b described above.

The third processing chamber CB3 may receive the substrate WF from the second processing chamber CB2 and may perform a bake process to completely dry the substrate WF. On a hot plate in the third processing chamber CB3, the bake process may be performed on the substrate WF at a temperature of about 120° C. to about 170° C. for about 30 seconds to about 120 seconds. In other words, due to the bake process in the third processing chamber CB3, the substrate WF may be maintained in the dry state.

The fourth processing chamber CB4 may receive the substrate WF from the third processing chamber CB3 and may perform a cooling process to lower the temperature of the substrate WF. A cooling process may be performed on a cooling plate in the fourth processing chamber CB4. In other words, due to the cooling process in the fourth processing chamber CB4, the substrate WF may be maintained in the dry state.

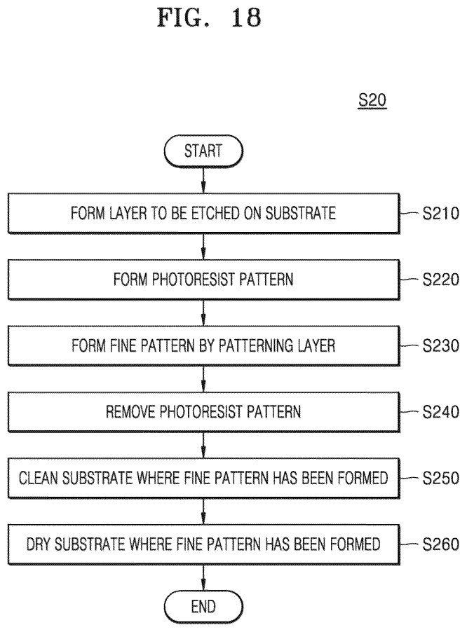

FIG. 18 is a flowchart of a fine pattern forming method S20 using a substrate processing apparatus 10, according to an embodiment.

Referring to FIG. 18, the fine pattern forming method S20 may include a process sequence of first through sixth operations S210 through S260.

When a certain embodiment is implemented differently, a particular process sequence may also be executed differently from the sequence to be described. For example, in some embodiments, two consecutively described processes may be performed substantially at the same time or in a sequence opposite to the sequence to be described.

The fine pattern forming method S20 according to the embodiment may include first operation S210 of forming a layer to be etched on a substrate, second operation S220 of forming a photoresist pattern, third operation S230 of forming a fine pattern by patterning the layer to be etched, fourth operation S240 of removing the photoresist pattern, fifth operation S250 of cleaning the substrate in which the fine pattern is formed, and sixth operation S260 of drying the substrate in which the fine pattern is formed.

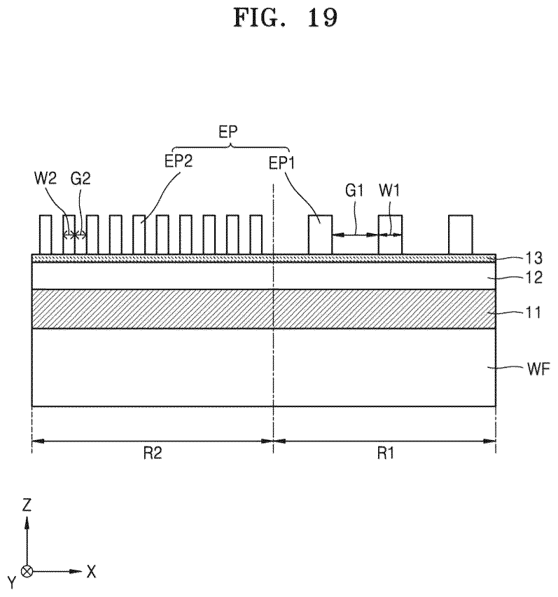

Technical characteristics of each of first through sixth operations S210 through S260 are described in detail below with reference to FIGS. 19 through 21.

FIGS. 19 through 21 are cross-sectional views to explain the fine pattern forming method S20 of FIG. 18 according to a process sequence, according to an embodiment.

Referring to FIG. 19, an etching target layer 11 may be formed on the substrate WF, a first mask layer 12 and a second mask layer 13 may be formed on the etching target layer 11, and an EUV photoresist pattern EP may be formed on the second mask layer 13.

The substrate WF may include a semiconductor material and may include a Group IV semiconductor or a Group III-V compound semiconductor. For example, the Group IV semiconductor may include silicon (Si), germanium (Ge), or silicon-germanium. The substrate WF may be provided as a bulk wafer or a wafer including an epitaxial layer. Although not illustrated, unit elements used for forming semiconductor devices, such as various types of active elements and passive elements, may be formed on the substrate WF. The substrate WF may be divided into a first region R1 and a second region R2.

The etching target layer 11 may be arranged on the substrate WF. The etching target layer 11 may include a single layer or a multilayer in which a plurality of material layers are stacked. The etching target layer 11 may include a material layer having etch selectivity with respect to the first and second mask layers 12 and 13. For example, the etching target layer 11 may include polysilicon, but is not limited thereto.

The first and second mask layers 12 and 13 may include various material layers for forming a target pattern on the etching target layer 11. The first mask layer 12 may be formed on the etching target layer 11, and the second mask layer 13 may be formed on the first mask layer 12.

The first and second mask layers 12 and 13 may be configured to have various thicknesses for forming the target pattern on the etching target layer 11. For example, the thickness of the second mask layer 13 may be less than the thickness of the first mask layer 12.

The EUV photoresist pattern EP may be formed on the second mask layer 13. The EUV photoresist pattern EP may be formed by forming, exposing, and developing a photoresist film that reacts to the EUV light by using an EUV exposure device (not illustrated).

The EUV photoresist pattern EP may include a first line pattern EP1 and a second line pattern EP2 according to a formation position. In this case, for convenience of explanation, a pattern formed in the first region R1 of the first and second line patterns EP1 and EP2 may be referred to as a plurality of first patterns EP1 and a pattern formed in the second region R2 of the first and second line patterns EP1 and EP2 may be referred to as a plurality of second patterns EP2.

The plurality of first patterns EP1 may include a first line-and-space pattern, in which the plurality of first patterns EP1 have a first width W1 of the same mask line and extend in parallel with each other in the second horizontal direction (Y direction), while being apart from each other in the first horizontal direction (X direction) at the same first gap G1. The plurality of second patterns EP2 may include a second line-and-space pattern, in which the plurality of second patterns EP2 have the same second width W2 of the same mask line and extend in parallel with each other in the second horizontal direction (Y direction), while being apart from each other in the first horizontal direction (X direction) at the same second gap G2.

In some embodiments, the first gap G1 of the plurality of first patterns EP1 may be formed to be greater than the second gap G2 of the plurality of second patterns EP2. In some embodiments, the first width W1 of the plurality of first patterns EP1 may be formed to be greater than the second width W2 of the plurality of second patterns EP2. However, this is an example for convenience of explanation and embodiments are not limited thereto.

A drying process may be performed on the substrate WF on which the first and second line patterns EP1 and EP2 are formed. Referring to FIG. 1 also, the substrate processing apparatus 10 described above may, by including the step portion 110S and the round portion 110R, reduce the flow rate of the processing fluid PF and/or the distribution of the flow rate of the processing fluid PF on the substrate WF and reduce the size of the dead zone DZ inside the processing space PS. Accordingly, it may be possible to efficiently prevent the leaning phenomenon of the plurality of second patterns EP2 in the second region R2 of the substrate WF and improve the uniformity of the drying process of the substrate WF.

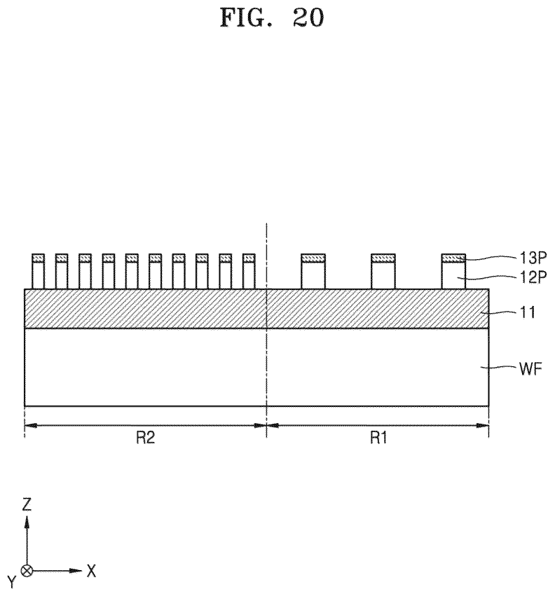

Referring to FIG. 20, by using the dried EUV photoresist pattern (refer to EP in FIG. 19) as an etching mask, the first and second mask layers 12 and 13 thereunder may be sequentially etched.

First and second mask patterns 12P and 13P may be formed by using the dried EUV photoresist pattern (refer to EP in FIG. 19) as an etching mask and anisotropically etching the first and second mask layers (refer to 12 and 13 in FIG. 19). For example, as an anisotropic etching method for forming the first and second mask patterns 12P and 13P, a dry etching process such as a reactive ion etching (RIE) process or an inductively coupled plasma (ICP) etching process may be used.

Next, the dried EUV photoresist pattern (refer to EP in FIG. 19) may be removed. The dried EUV photoresist pattern (refer to EP in FIG. 19) may be removed by using ashing and strip processes. The removing process of the dried EUV photoresist pattern (refer to EP in FIG. 19) may be performed under conditions in which etching of the first and second mask patterns 12P and 13P is suppressed.

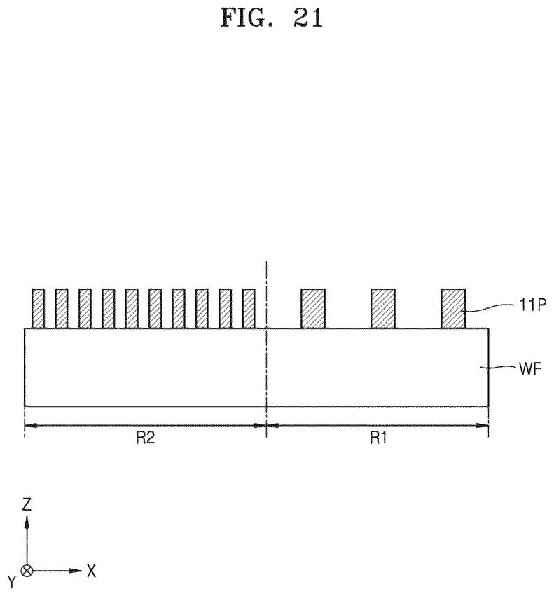

Referring to FIG. 21, a target pattern 11P may be formed on the substrate WF by using the first and second mask patterns (refer to 12P and 13P in FIG. 20) as etching masks to etch an etching target layer (refer to 11 in FIG. 20) arranged under the first and second mask patterns 12P and 13P.

The target pattern 11P may be formed by using the first and second mask patterns (refer to 12P and 13P in FIG. 20) as etching masks to anisotropically etch the etching target layer (refer to 11 in FIG. 20). As an anisotropic etching method for forming the target pattern 11P, a dry etching process, such as an RIE process and an ICP etching process, may be used. The target pattern 11P may have a line-and-space pattern in which the target patterns 11P are apart from each other in the first horizontal direction (X direction and extend in parallel with each other in the second horizontal direction (Y direction).

Next, both of the first mask and the second mask pattern (respectively refer to 12P and 13P in FIG. 20) arranged on the upper portion of the target pattern 11P may be removed. The removing process may be performed under a condition in which etching of the target pattern 11P is suppressed.

While various embodiments have been particularly shown and described with reference to the drawings, it will be understood that various change in form and details may be made therein without departing from the spirit and scope of the following claims.

What is claimed is:

1. A substrate processing apparatus comprising:
a processing chamber including a processing space;
a substrate support configured to receive a substrate and support the substrate in the processing chamber;
a fluid supply pipe arranged at a lower portion of the processing chamber; and
a fluid supply device configured to supply a processing fluid to the processing space through the fluid supply pipe,
wherein the processing chamber comprises a step portion and a round portion both in an upper surface that defines the processing space, and
wherein a first horizontal separation distance from a center of the processing chamber to the step portion is greater than a second horizontal separation distance from the center of the processing chamber to an edge of the substrate.

2. The substrate processing apparatus of claim 1, wherein the step portion is recessed vertically upward from the upper surface.

3. The substrate processing apparatus of claim 1, wherein:
the first horizontal separation distance from the center of the processing chamber to the step portion is less than a third horizontal separation distance from the center of the processing chamber to the round portion.

4. The substrate processing apparatus of claim 1, wherein the step portion has an angle of about 90° to about 180° with respect to the upper surface.

5. The substrate processing apparatus of claim 1, wherein a vertical level of the round portion decreases away from the center of the processing chamber in a horizontal direction.

6. The substrate processing apparatus of claim 1, wherein:
in a plan view, a second distance from the edge of the substrate to the step portion is about ⅔ or less than a first distance from the edge of the substrate to a side surface of the processing chamber.

7. The substrate processing apparatus of claim 1, wherein a distance from the upper surface of the processing chamber to the upper surface of the substrate is about 2 mm to about 10 mm.

8. The substrate processing apparatus of claim 1, wherein the processing fluid includes carbon dioxide.

9. A substrate processing apparatus comprising:
a processing chamber including a processing space;
a substrate support configured to receive a substrate and support the substrate in the processing chamber;
a fluid supply pipe arranged at a lower portion of the processing chamber; and
a fluid supply device configured to supply a processing fluid to the processing space through the fluid supply pipe,
wherein the processing chamber comprises a step portion and a round portion on an upper surface that defines the processing space, and
wherein the step portion is vertically aligned with an edge of the substrate.

10. The substrate processing apparatus of claim 9, wherein the step portion contacts the round portion.

11. The substrate processing apparatus of claim 9, wherein the step portion has an angle of about 90° with respect to the upper surface.

12. The substrate processing apparatus of claim 9,
wherein the processing chamber comprises an upper body and a lower body, and
wherein the upper body is configured to be coupled to the lower body to cover a space provided by the lower body.

13. The substrate processing apparatus of claim 12, wherein the upper body has a symmetrical shape with respect to a center axis of the upper body.

14. The substrate processing apparatus of claim 9, wherein, in the processing space, a center of turbulence generated by high pressure inflow of the processing fluid is formed at a location spaced away from the edge of the substrate.

15. The substrate processing apparatus of claim 9, wherein a diameter of the substrate support is less than a diameter of the substrate.

16. The substrate processing apparatus of claim 9, wherein the substrate comprises an exposed extreme ultra-violet (EUV) photoresist pattern.

17. The substrate processing apparatus of claim 9, wherein the processing fluid flows into the processing space via a lower portion of the substrate support.

18. A substrate processing method comprising:
loading a substrate into a processing space of a processing chamber;
supplying a processing fluid into the processing chamber through at least one of a first supply pipe provided on a bottom wall of the processing chamber or a second supply pipe provided on an upper wall of the processing chamber; and
exhausting the processing fluid in the processing chamber through an exhaust pipe provided on the bottom wall of the processing chamber,
wherein the processing chamber comprises an upper processing chamber and a lower processing chamber, and
wherein the upper processing chamber comprises a step portion and a round portion.

19. The substrate processing method of claim 18, wherein:
a first horizontal separation distance from a center of the processing chamber to an edge of the substrate is equal to or less than a second horizontal separation distance from the center of the processing chamber to the step portion.

20. The substrate processing method of claim 18, wherein the step portion has an angle of about 90° to about 180° with respect to an upper surface that defines the processing space.
